(19) United States
(12) Patent Application Publication
(10) Pub. No.: US 2007/0201294 A1
(43) Pub. Date: Aug. 30, 2007

(54) Control circuit for power supply device, power supply device, and control method thereof

(75) Inventors: Hidekiyo Ozawa, Kasugai (JP); Toru Nakamura, Kasugai (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/447,022

(22) Filed: Jun. 6, 2006

(30) Foreign Application Priority Data
Feb. 24, 2006 (JP) 2006-047819

(51) Int. Cl. G11C 5/14

(52) U.S. Cl. 365/226

(57) ABSTRACT

A control circuit for a power supply device, a power supply device, and a control method thereof are provided where the output voltages to be supplied to various devices are determined and set up to optimum levels rapidly and efficiently. A control circuit 10A in a power supply device supplies a device 60, which supplies an initial voltage and then demands to receive a required level of voltage which is different from an initial voltage supplied beforehand, with the required level of voltage ranging from V1 to V3. The control circuit 10A comprises a communication unit 21 for receiving a demand level such as V1 and a storage unit 22, including REG1 to REG3, for storing an initial setting level beforehand for determining the initial voltage and the demand level received by the communication unit 21. The initial voltage or the required voltage ranging from V1 to V3 can controlled in response to the initial setting level or the demand level.

### CROSS-REFERENCE TO RELATED APPLICATIONS

This application is based upon and claims the benefit of priority from each of the prior Japanese Patent Application No. 2006-047819 filed on Feb. 24, 2006, the entire contents of which are incorporated herein by reference.

### BACKGROUND OF THE INVENTION

1. Field of the Invention

The present invention relates to a control circuit for a power supply device, a power supply, and a method of controlling the same.

2. Description of the Related Art

As integrated circuits (for example, LSIs or ICs) are commonly varied in the manufacturing process, their transistors may not be uniform in the threshold voltage level or the resistance level. Also, depending on the using conditions (including the ambient temperature), such a integrated circuit maybe varied in the threshold voltage level or the resistance level of its transistors. With its transistors not uniform in the threshold voltage level or the resistance level, the integrated circuit will hence be varied in the delay time and thus the operating speed. For eliminating any significant change in the operating speed, a power supply device is provided for applying the integrated circuit with an optimum voltage in relation to the threshold voltage level or the resistance level.

An electronic device and an integrated circuit controlled by the power supply device are disclosed in Japanese Unexamined Patent Publications No. 2000-228833 and No. 2001-332695 respectively. The electronic device disclosed in No. 2000-228833 is arranged in which its associated battery is charged by an external power supply and discharged for operating system components. Particularly, the output of its power supply device (power supply) is controlled so that a sum of the operating power of the system components and the charge to the battery remains substantially uniform. The electronic device allows a controller of the power supply device to monitor the output (current) of the power supply device and control the power supplied to the system components and the charge to the associated battery, thus minimizing the consumption of the power.

The integrated circuit disclosed in No. 2001-332695 includes a first logic gate to be energized with a first set of potentials having relatively small in the potential difference and a second logic gate to be energized with a second set of potentials having relatively great in the potential difference while the reference potential at the MIS transistor is shared commonly by the first and second logic gates. The integrated circuit allows the amplitude of a voltage output of the MIS transistor in the second logic gate to become greater than the amplitude of a voltage output of the MIS transistor in the first logic gate, thus operating the second logic gate at a higher speed than that of the first logic gate. Also, since the power consumption of each logic gate is proportional to a square of the amplitude of the voltage output of the MIS transistor in the integrated circuit, the amplitude of a voltage output of the MIS transistor in the first logic gate is set smaller than the amplitude of a voltage output of the MIS transistor in the second logic gate, whereby the first logic gate can be operated with a lower power than that of the second logic gate.

### SUMMARY OF THE INVENTION

A power supply device is connected with various devices including the above described integrated circuit. It is hence necessary for the power supply device that its output voltages are modified to their optimum levels to match the connected device while preventing the operating speed of the integrated circuit from being significantly varied due to any variations in the threshold voltage level or the resistance level in the transistors.

However, the voltage outputs of the power supply device have to be modified to optimum levels every time when the power supply device is started up. As the voltage outputs are modified from their fixed initial settings to optimum levels which are varied from one device to another, the time required for their modification will be lengthened significantly. In other words, it will be difficult to modify the voltage output to their optimum levels at a higher speed.

Also, the power supply device permits its voltage outputs to be modified from the fixed initial settings to the optimum levels depending on each type of the connected device and its setting up action will thus stay rather low in the efficiency.

The present invention has been developed in view of the above drawback and its object is to provide a control circuit for a power supply device, a power supply device, and a control method thereof where the voltage outputs to be supplied to a variety of devices can be set up to optimum levels rapidly and efficiently.

A control circuit for a power supply device according to a first aspect of the present invention, and a power supply device according to a second aspect of the present invention, for supplying a required voltage to a device which supplies an initial voltage and then demands to receive the required voltage different from the initial voltage, comprise: a communication unit for receiving a demand level for the required voltage; and a storage unit for storing an initial setting level used to determine the initial voltage beforehand and storing the demand level received by the communication unit, wherein the initial voltage or the required voltage is controlled in response to the initial setting level or the demand level.

The control circuit for a power supply device according to the first aspect of the present invention and the power supply device according to the second aspect of the present invention comprise a communication unit for receiving a demand level for the required voltage and a storage unit for storing an initial setting level used for determining the initial voltage beforehand and for storing the demand level received by the communication unit, wherein the initial voltage or the required voltage is controlled in response to the initial setting level or the demand level. As the result, the time required for directly setting up the voltages to the optimum levels required by the connected device in response to the demand levels stored in the storage unit can be minimized more than that the adjusting the voltages to optimum levels for a device every time when the power supply device is started up. In other words, the voltages to be supplied to the device can be set up to the optimum levels efficiently and rapidly.

A control method of a power supply device according to a third aspect of the present invention for supplying a required voltage to a device which supplies an initial voltage and then demands to receive the required voltage different from the initial voltage, comprises steps of: receiving a demand level for the required voltage; storing an initial setting level used to determine the initial voltage beforehand and storing the demand level received; and controlling the initial voltage or the required voltage in response to the initial setting level or the demand level.

The control method of a power supply device according to the third aspect of the present invention comprises the steps of receiving a demand level for the required voltage of the device, storing an initial setting level used for determining the initial voltage beforehand and storing the demand level received, and controlling the initial voltage or the required voltage in response to the stored initial setting level or the stored demand level. As the result, the time required for directly setting up the voltages to the optimum levels required by the connected device in response to the demand levels stored can be minimized more than that the adjusting the voltages to optimum levels for a device every time when the power supply device is started up. In other words, the voltages to be supplied to the device can be set up to the optimum levels efficiently and rapidly.

The above and further objects and novel features of the invention will more fully appear from the following detailed description when the same is read in connection with the accompanying drawings. It is to be expressly understood, however, that the drawings are for the purpose of illustration only and are not intended as a definition of the limits of the invention.

### BRIEF DESCRIPTION OF THE DRAWINGS

FIG. 1 is a block diagram showing the connection between a power supply device and an electronic device according to one embodiment of the present invention;

FIG. 2 is a circuitry diagram of the power supply device connected to the electronic device; and

FIG. 3 is a schematic view of the electronic device connected with the power supply device.

### DETAILED DESCRIPTION OF THE PREFERRED EMBODIMENT

### Embodiment

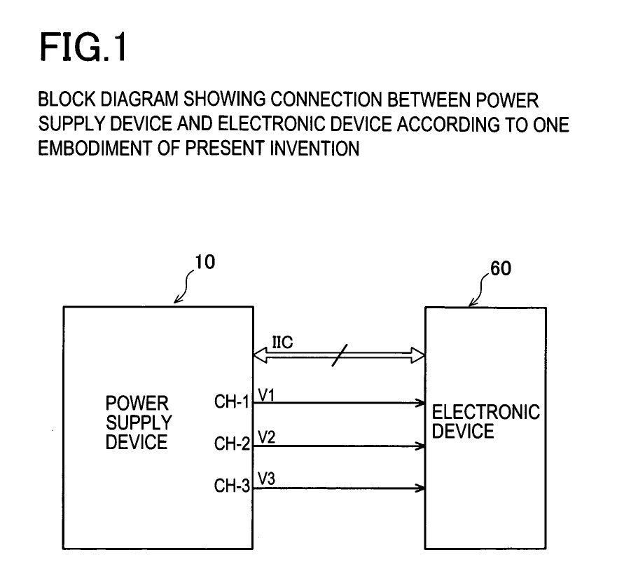

One embodiment of the present invention will be described with reference to FIGS. 1 to 3. A power supply device 10 of the embodiment is connected to an electronic device 60 (external device) by an IIC bus IIC (a communicating means), as shown in FIG. 1. The IIC bus IIC is provided for exchanging a variety of data between the power supply device 10 and the electronic device 60. The power supply device 10, as shown, has three (CH-1 to CH-3) channel outputs. The electronic device 60 consists of one or more integrated circuits.

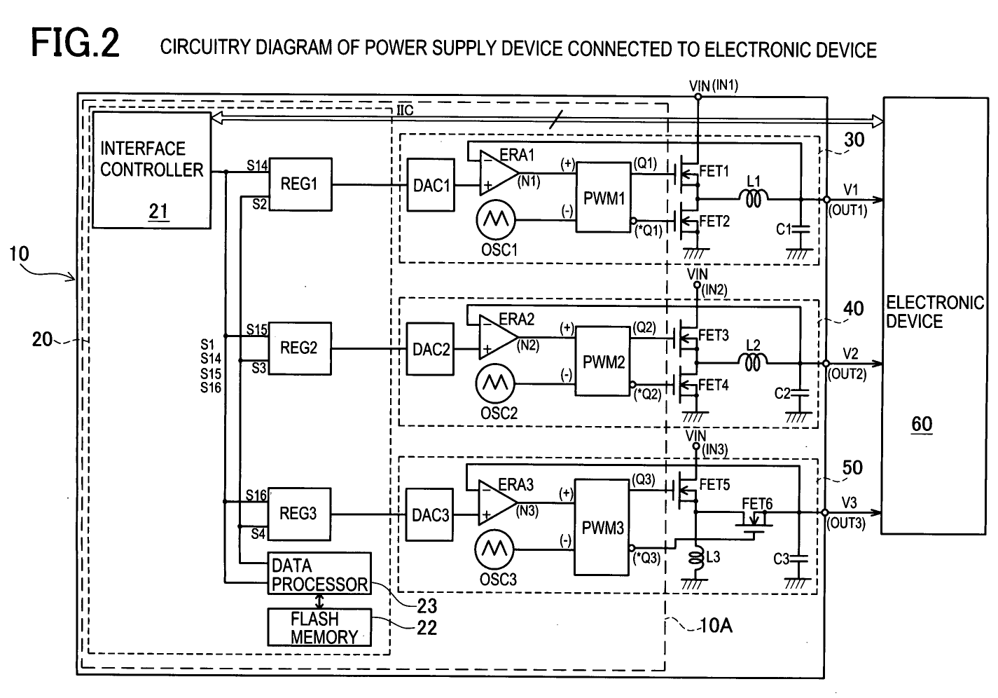

As shown in FIG. 2, the power supply device 10 comprises a communication controller 20 and first to third, DC/DC converters 30 to 50. The communication controller 20 includes an interface controller 21, a flash memory 22, a data processor 23 (e.g., an MPU), and three registers REG1 to REG3. Denoted by 10A in the drawing is a control circuit of the power supply device 10.

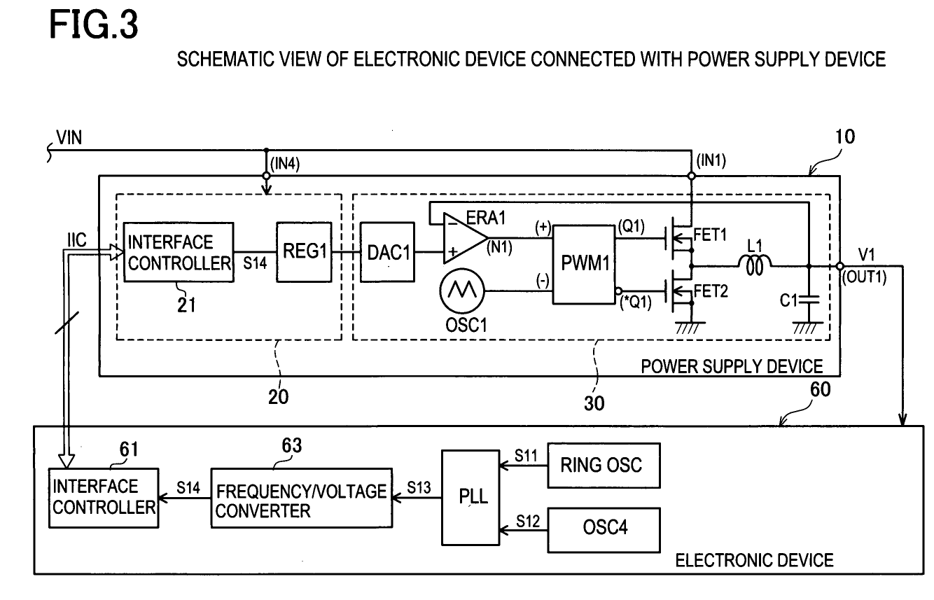

The interface controller 21 is connected with an IIC bus IIC. As apparent from FIGS. 2 and 3, the IIC bus IIC is connected to an interface controller 61 of the electronic device 60. The electronic device 60 includes a ring oscillator RINGOSC and an oscillator OSC4 as shown in FIG. 3. The ring oscillator RINGOSC and the oscillator OSC4 are connected to a phase-locked loop circuit PLL. The phase-locked loop circuit PLL is connected to a frequency/voltage converter 63. The frequency/voltage converter 63 is then connected with the interface controller 61.

As shown in FIG. 2, the resisters REG1, REG2, and REG3 and the data processor 23 are connected in parallel with the interface controller 21. The flash memory 22 is connected to the data processor 23 which are then connected to the registers REG1, REG2, and REG3 in parallel.

The register REG1, as shown, is connected to a D/A converter DAC1 of the first DC/DC converter 30. The register REG2 is connected to a D/A converter DAC2 of the second DC/DC converter 40. The register REG3 is connected to a D/A converter DAC3 of the third DC/DC converter 50.

The first DC/DC converter 30 includes a main switching transistor FET1, a sync side switching transistor FET2, a chalk coil L1, and a capacitor C1 as shown. The main switching transistor FET1 is connected at the drain to an input terminal (IN1) for receiving a direct current input voltage VIN. The direct current input voltage VIN is applied via an input terminal (IN4) to the communication controller 20, as shown in FIG. 3, as well as to the main switching transistor FET1. The source of the main switching transistor FET1 is connected to the drain of the sync side switching transistor FET2. The source of the sync side switching transistor FET2 is connected to the ground. Further, the source of the main switching transistor FET1 and the drain of the sync side switching transistor FET2 are connected to the chalk coil L1. The chalk coil L1 is connected to an output terminal (OUT1). The capacitor C1 is connected between the output terminal (OUT1) and the ground. The output terminal (OUT1) is connected to the electronic device 60.

The first DC/DC converter 30 further includes an error amplifier ERA1, a D/A converter DAC1, a triangle wave oscillator OSC1, and a PWM comparator PWM1. The inverted input terminal of the error amplifier ERA1 is connected to the output terminal (OUT1). The non-inverted input terminal of the error amplifier ERA1 is connected to the D/A converter DAC1.

The triangle wave oscillator OSC1 outputs a triangle wave signal. The triangle wave signal oscillates within a range of a voltage amplitude (for example, between 1.0 V and 2.0 V). The triangle wave oscillator OSC1 may be composed of an OP amplifier, a resistor, and a capacitor, etc.

The PWM comparator PWM1 has a positive input terminal (+) and a negative input terminal (−). The positive input terminal (+) is connected to the output terminal (N1) of the error amplifier ERA1 while the negative input terminal (−) is connected to the triangle wave oscillator OSC1. The output terminal (Q1) of the PWM comparator PWM1 is also connected to the gate of the main switching transistor FET1 and the inverted output terminal (*Q1) of the PWM comparator PWM1 is connected to the gate of the sync side switching transistor FET2.

The second DC/DC converter 40 is substantially equal in the structure of the first DC/DC converter 30. More particularly, the second DC/DC converter 40 in the present embodiment can be constructed by replacing the error amplifier ERA1, the D/A converter DAC1, the triangle wave oscillator OSC1, the PWM comparator PWM1, the main switching transistor FET1, the sync side switching transistor FET2, the chalk coil L1, and the capacitor C1 in the first DC/DC converter 30 with an error amplifier ERA2, a D/A converter DAC2, a triangle wave oscillator OSC2, a PWM comparator PWM2, a main switching transistor FET3, a sync side switching transistor FET4, a chalk coil L2, and a capacitor C2 respectively. The triangle wave oscillator OCS2, like the triangle wave oscillator OSC1, outputs a triangle wave signal which oscillates within a voltage amplitude range (for example, between 1.0 V and 2.0 V).

Denoted by N2, IN2, and OUT2 are the output terminal of the error amplifier ERA2, the input terminal of the second DC/DC converter 40, and the output terminal of the second DC/DC converter 40 respectively. The output terminal and the inverted output terminal of the PWM comparator PWM2 are denoted by Q2 and *Q2 respectively. The output terminal OUT2 is connected to the electronic device 60.

The third DC/DC converter 50 includes an NMOS transistor FET5, an NMOS transistor FET6, a chalk coil L3, and a capacitor C3. The NMOS transistor FET5 is connected at the drain to an input terminal IN3 for receiving a direct current input voltage VIN as shown. The source of the NMOS transistor FET5 is connected to the chalk coil L3 which is in turn connected to the ground.

The source of the NMOS transistor FETS is connected to the drain of the NMOS transistor FET6. Further, the source of the NMOS transistor FET6 is connected to an output terminal OUT3. The capacitor C3 is connected between the output terminal OUT3 and the ground. The output terminal OUT3 is connected to the electronic device 60.

The third DC/DC converter 50 includes an error amplifier ERA3, a D/A converter DAC3, a triangle wave oscillator OSC3, and a PWM comparator PWM3. The inverted input terminal of the error amplifier ERA3 is connected to the output terminal OUT3. The non-inverted input of the error amplifier ERA3 is connected to the D/A converter DAC3. The triangle wave oscillator OSC3, like the triangle wave oscillators OSC1 and OSC2, outputs of a triangle wave signal.

The positive input terminal (+)of the PWM comparator PWM3 is connected to an output terminal N3 of the error amplifier ERA3 and the negative input terminal (−) to the triangle wave oscillator OSC3. The output terminal Q3 of the PWM comparator PWM3 is connected to the gate of the NMOS transistor FET5. The inverted output terminal *Q3 of the PWM comparator PWM3 is connected to the gate of the NMOS transistor FET6.

The control method of the power supply device 10 will now be described. When the power supply device 10 shown in FIG. 2 is energized, its interface controller 21 outputs a reset signal S1 to the data processor 23. Upon receiving the reset signal S1, the data processor 23 accesses the flash memory 22 for reading an initial data. The initial data is provided for setting the voltage V1 to be supplied to the electronic device 60 connected to the output terminal OUT1 of the first DC/DC converter 30 to an initial level as having been stored beforehand at a nonvolatile mode in the flash memory 22. More specifically, the initial voltage is set to a rated level (for example, 5 V) of the electronic device 60 as corresponding to an initial setting level according to the present invention. The data processor 23 outputs a voltage command signal S2 corresponding to the initial data to the register REG1. As the flash memory 22 stores the initial data (initial setting level) at the nonvolatile mode, it corresponds to a nonvolatile storage (memory) according to the present invention. The initial setting level is not limited to the rated level (5 V) of the electronic device 60 but may be selected from the permissive range of the rated voltage (for example, from 4.5 V to 5.5 V).

The register REG1 stores the voltage command signal S2 and then outputs the signal S2 to the D/A converter DAC1 of the first DC/DC converter 30. When the power supply device 10 is energized, the register REG1 stores the voltage command signal S2 of the initial data (initial setting level) in the volatile mode and corresponds to a register unit (a volatile storage unit) according to the present invention.

The D/A converter DAC1 produces from the voltage command signal S2 an analog voltage signal (a reference voltage) which is then received by the non-inverted input of the error amplifier ERA1. As shown, the voltage V1 is fed back to the inverted input terminal of the error amplifier ERA1. The error amplifier ERA1 compares the feedback voltage V1 with the reference voltage to output an error output voltage to the positive input terminal (+) of the PWM comparator PWM1.

The negative input terminal (−) of the PWM comparator PWM1 receives the triangle wave signal from the triangle wave oscillator OSC1. The PWM comparator PWM1 compares the voltage of the triangle wave signal with the error output voltage from the error amplifier ERA1.

When the error output voltage is greater than the voltage of the triangle wave signal, the PWM comparator PWM1 outputs a PWM signal at the high level from the output terminal Q1. Simultaneously, the PWM comparator PWM1 outputs an inverted PWM signal at the low level from the inverted output terminal *Q1. When the error output voltage is smaller than the voltage of the triangle wave signal, the PWM comparator PWM1 outputs the PWM signal at the low level from the output Q1. Simultaneously, the PWM comparator PWM1 outputs the inverted PWM signal at the high level from the inverted output terminal *Q1.

The PWM signal is inputted to the gate of the main switching transistor FET1. The main switching transistor FET1 is turned on when the PWM signal is at the high level and off when at the low level. The inverted PWM signal is inputted to the gate of the sync side switching transistor FET2. The sync side switching transistor FET2 is turned off when the inverted PWM signal is at the low level and on when at the high level. By repeating the shift of the PWM signal between the high level and the low level and the shift of the inverted PWM signal between the low level and the high level, the voltage V1 is adjusted to the initial level (5 V in this embodiment) which is then supplied via the output terminal OUT1 to the electronic device 60. Since the first DC/DC converter 30 compares the feedback voltage V1 with the analog signal (reference voltage) converted from the voltage command signal S2 and adjusts the voltage V1 to the initial setting through turning the two switching transistors FET1 and FET2 on and off, it corresponds to a voltage controller according to the present invention.

The integrated circuit in the electronic device 60 may be varied in the threshold voltage or the resistance level of the transistor. The optimum level of the voltage for the integrated circuit is thus not uniform depending on the threshold voltage or the resistance level, etc. For obtaining the optimum level of the voltage V1 (for example, 4.8 V as corresponding to a required level for the required voltage according to the present invention), the electronic device 60 outputs a voltage adjust signal S14 (See FIG. 3) to the interface controller 21, which will be explained below.

As shown in FIG. 3, the phase-locked loop circuit PLL receives a frequency signal S11 from the ring oscillator RINGOSC and a reference frequency signal S12 from the oscillator OSC4. The ring oscillator RINGOSC, for example, includes a loop circuit where a group of inverters may be connected in an odd number of stages. The period of the frequency signal S11 is determined by the product of the odd number of the inverter stages and the delay time of the inverters. The delay time is varied depending on the threshold voltage or the resistance level, etc. Accordingly, the period of the frequency signal S11 is varied depending on the threshold voltage or the resistance level, etc. The phase-locked loop circuit PLL compares the frequency signal S11 with the reference frequency signal S12 to output an output signal S13. The output signal S13 represents a difference between the frequency signal S11 and the reference frequency signal S12. The output signal S13 is then inputted to the frequency/voltage converter circuit 63. The frequency/voltage converter circuit 63 outputs the voltage adjust signal S14 converted from the output signal S13. If needed, the voltage adjust signal S14 is transferred from the interface controller 61 via the IIC bus IIC to the interface controller 21 in the power supply device 10. The voltage adjust signal S14 adjusts the voltage V1 so as to eliminate the difference between the reference frequency signal S11 and the reference frequency signal S12. This allows the first DC/DC converter 30 to supply the electronic device 60 with the optimum level (4.8 V) of the voltage V1. As the interface converter 21 receives the voltage adjust signal S14 for adjusting the voltage V1 to an optimum level, it corresponds to a communication unit according to the present invention.

The interface controller 21 outputs the voltage adjust signal S14 to the register REG1 and the data processor 23 as shown in FIG. 2. The resistor REG1 stores the voltage adjust signal S14 in place of the voltage command signal S2 and then outputs the voltage adjust signal S14 to the converter DAC1 of the first DC/DC converter 30. As the resistor REG1 stores the voltage adjust signal S14 received by the interface controller 21 at the volatile mode when the voltage V1 is supplied from the power supply device 10 to the electronic device 60, it corresponds to a register unit according to the present invention. The data processor 23 writes down a voltage adjusting data (a received voltage level) corresponding to the voltage adjust signal S14 in the flash memory 22, which replaces the initial data (initial setting level). Since the flash memory 22 stores the voltage adjusting data (a received voltage level) of the voltage adjust signal S14 received at the interface controller 21 and written by the data processor 23, it corresponds to a storage unit according to the present invention.

The D/A converter DAC1 outputs an analog voltage signal (a reference voltage) corresponding to the voltage adjust signal S14 to the non-inverted input terminal of the error amplifier ERA1. As understood from FIG. 2, the error amplifier ERA1 compares the feedback voltage V1 with the reference voltage to output an error output voltage to the positive input terminal (+) of the PWM comparator PWM1.

Similar to the above mentioned control method, the PWM comparator PWM1 outputs a PWM signal and an inverted PWM signal to the gate of the main switching transistor FET1 and the gate of the sync side switching transistor FET2 respectively. Similar to the above control method, the PWM signal is repeatedly shifted between the high level and the low level while the inverted PWM signal is repeated shifted between the low level and the high level, whereby the voltage V1 can be controlled to the optimum level (4.8 V) supplied to the electronic device 60 via the output terminal OUT1. Since the first DC/DC converter 30 compares the feedback voltage V1 and the analog signal (reference voltage) corresponding to the voltage adjust signal S14 and adjusts the voltage V1 to the optimum level through turning the two switching transistors FET1 and FET2 on and off, it corresponding to a voltage controller unit according to the present invention.

Upon receiving the reset signal S1, the data processor 23 accesses the flash memory 22 for reading an initial data of the voltage V2. Then, the data processor 23 outputs a voltage command signal S3 to the register REG2. The voltage command signal S3 is used for adjusting the voltage V2 supplied to the electronic device 60 connected to the output terminal OUT2 of the second DC/DC converter 40 to an initial setting level. In this embodiment, the initial setting level is equal to a rated voltage (for example, 2.5 V) of the electronic device 60.

The register REG2 stores the voltage command signal S3 and outputs the signal S3 to the D/A converter DAC2 of the second DC/DC converter 40. As the register REG2 stores the voltage command signal S3 corresponding to the initial data (initial setting level) in the volatile mode, it corresponds to a register unit (a volatile storage) according to the present invention.

The D/A converter DAC2 outputs an analog voltage signal (a reference voltage) corresponding to the voltage command signal S3 to the non-inverted input terminal of the error amplifier ERA2. As shown, the voltage V2 is fed back to the inverted input terminal of the error amplifier ERA2. The error amplifier ERA2 compares the feedback voltage V2 with the reference voltage to output an error output voltage to the positive input terminal (+) of the PWM comparator PWM2.

The triangle wave signal is inputted to the negative input terminal (−) of the PWM comparator PWM2 by the triangle wave oscillator OSC2. Similar to the PWM comparator PWM1 mentioned above, the PWM comparator PWM2 outputs the PWM signal and the inverted PWM signal to the gate of the main switching transistor FET3 and the gate of the sync side switching transistor FET4 respectively. By repeating the shift of the PWM signal between the high level and the low level and the shift of the inverted PWM signal between the low level and the high level in the same manner as of the control method of the voltage V1, the voltage V2 is adjusted to the initial level (2.5 V in this embodiment) and then transferred to the electronic device 60 via the output terminal OUT2. Since the second DC/DC converter 40 compares the feedback voltage V2 with the analog signal (reference voltage) corresponding to the voltage command signal S3 and adjusts the voltage V2 to the initial setting through turning the two switching transistors FET3 and FET4 on and off, it presents a voltage controller unit according to the present invention.

The voltage V2 to be supplied to the electronic device 60 by the second DC/DC converter 40 may however be varied depending on the threshold voltage or the resistance level, etc. and stay not at an optimum level (for example, 2.7 V). In such an unfavorable case, the electronic device 60 outputs a voltage adjust signal S15 (See FIG. 2) along the IIC bus IIC to the interface controller 21, similar to the method shown in FIG. 3. The voltage adjust signal S15 is used for directing the second DC/DC converter 40 to supply the electronic device 60 with an optimum level of the voltage V2 (in this embodiment, 2.7V).

The voltage adjust signal S15 is then outputted to the register REG2 and the data processor 23 by the interface controller 21. The register REG2 stores the voltage adjust signal S15 in place of the voltage command signal S3 and outputs the signal S15 to the D/A converter DAC2 of the second DC/DC converter 40. As the register REG2 stores the voltage adjust signal S15 received by the interface controller 21 in a volatile mode with the power supply device 10 supplying the electronic device 60 with the voltage V2, it corresponds to a register unit according to the present invention. On the other hand, the data processor 23 writes down data (received voltage level) of the voltage adjust signal S15 in the flash memory 22 replacing the initial data (initial setting level).

The D/A converter DAC2 outputs an analog voltage signal (a reference voltage) corresponding to the voltage adjust signal S15 to the non-inverted input terminal of the error amplifier ERA2. The error amplifier ERA2 compares the feedback voltage V2 with the reference voltage to output an error output voltage to the positive input terminal (+) of the PWM comparator PWM2.

The triangle wave signal is inputted to the negative input terminal (−) of the PWM comparator PWM2 by the triangle wave oscillator OSC2. The PWM comparator PWM2 outputs a PWM signal and an inverted PWM signal to the gate of the main switching transistor FET3 and the gate of the sync side switching transistor FET4 respectively. Similar to the above mentioned control method, the PWM signal is repeatedly shifted between the high level and the low level while the inverted PWM signal is repeated shifted between the low level and the high level, whereby the voltage V2 can be controlled to the optimum level (2.7 V) which is then supplied to the electronic device 60 via the output terminal OUT2. Since the second DC/DC converter 40 compares the feedback voltage V2 with the analog signal (reference voltage) corresponding to the voltage adjust signal S15 and adjusts the voltage V2 to the optimum level through turning the two switching transistors FET3 and FET4 on and off, it corresponds to a voltage controller unit according to the present invention.

Upon receiving the reset signal S1, the data processor 23 accesses the flash memory 22 for reading an initial data of the negative voltage V3. Then, the data processor 23 outputs a voltage command signal S4 to the register REG3. The voltage command signal S4 is used for adjusting the negative voltage V3 supplied to the electronic device 60 connected to the output terminal OUT3 of the third DC/DC converter 50 to an initial setting level. In this embodiment, the initial setting level is equal to a rated voltage (for example, −2.5 V) of the electronic device 60.

The register REG3 stores the voltage command signal S4 and outputs the signal S4 to the D/A converter DAC3 of the third DC/DC converter 50. As the register REG3 stores the voltage command signal S4 corresponding to the initial data (initial setting level) in the volatile mode, it corresponds to a register unit (a volatile storage unit) according to the present invention.

The D/A converter DAC3 outputs an analog voltage signal (a reference voltage) corresponding to the voltage command signal S4 to the non-inverted input terminal of the error amplifier ERA3. As shown, the voltage V3 is fed back to the inverted input terminal of the error amplifier ERA3. The error amplifier ERA3 compares the feedback voltage V3 with the reference voltage to output an error output voltage to the positive input terminal (+) of the PWM comparator PWM3.

The triangle wave signal is inputted to the negative input terminal (−) of the PWM comparator PWM3 by the triangle wave oscillator OSC3. Similar to the PWM comparator PWM1 or PWM2, the PWM comparator PWM3 outputs the PWM signal and the inverted PWM signal to the gate of the NMOS transistor FET5 and the gate of the NMOS transistor FET6 respectively. By repeating the shift of the PWM signal between the high level and the low level and the shift of the inverted PWM signal between the low level and the high level, the voltage V3 is adjusted to the initial level (−2.5 V in this embodiment) and supplied to the electronic device 60 via the output terminal OUT3. Since the third DC/DC converter 50 compares the feedback voltage V3 with the analog signal (reference voltage) corresponding to the voltage command signal S4 and adjusts the voltage V3 to the initial setting through turning the two switching transistors FETS and FET6 on and off, it corresponds to a voltage controller unit according to the present invention.

When the voltage V3 supplied from the third DC/DC converter 50 to the electronic device 60 is not at the optimum level (for example, −2.9 V) but another level (−2.5 V), the electronic device 60 outputs a voltage adjust signal S16 (See FIG. 2) along the IIC bus IIC to the interface controller 21, similar to the method shown in FIG. 3. The voltage adjust signal S16 is used for directing the third DC/DC converter 50 to supply the electronic device 60 with the optimum level (−2.9 V) of the voltage V3.

The interface controller 21 outputs the voltage adjust signal S16 to the register REG3 and the data processor 23. The register REG3 stores the voltage adjust signal S16 in place of the voltage command signal S4 and outputs the signal S16 to the D/A converter DAC3 of the third DC/DC converter 50. As the register REG3 stores the voltage adjust signal S16 received by the interface controller 21 in a volatile mode when the power supply device 10 supplies the voltage V3 to the electronic device 60, it corresponds to a register unit according to the present invention. On the other hand, the data processor 23 writes down data (received voltage level) corresponding to the voltage adjust signal S16 in the flash memory 22 replacing the initial data (initial setting level).

The D/A converter DAC3 outputs an analog voltage signal (a reference voltage) corresponding to the voltage adjust signal S16 to the non-inverted input terminal of the error amplifier ERA3. The error amplifier ERA3 compares the feedback voltage V3 with the reference voltage to output an error output voltage to the positive input (+) of the PWM comparator PWM3.

The PWM comparator PWM3 outputs a PWM signal and an inverted PWM signal to the gate of the NMOS transistor FET5 and the gate of the NMOS transistor FET6 respectively. Similar to the above mentioned control method, the PWM signal is repeatedly shifted between the high level and the low level while the inverted PWM signal is repeated shifted between the low level and the high level, whereby the voltage V3 can be controlled to the optimum level (−2.9 V) which is then supplied to the electronic device 60 via the output terminal OUT3. Since the third DC/DC converter 50 compares the feedback voltage V3 with the analog signal (reference voltage) corresponding to the voltage adjust signal S16 and adjusts the voltage V3 to the optimum level through turning the two NMOS transistors FETS and FET6 on and off, it corresponds to a voltage controller unit according to the present invention.

The power supply device 10 of this embodiment permits the data (the received voltage levels) of the voltage adjust signals S14 to S16 to remain stored in the flash memory 22 (a nonvolatile storage unit) even when the power is interrupted. When the power supply device 10 is switched on with the data (the received voltage levels) of the voltage adjust signals S14 to S16 remaining stored in the flash memory 22, its first to third DC/DC converters 30, 40, and 50 are activated to determine the voltages V1, V2, and V3 in response to the results of comparison between the voltages V1, V2, and V3 and their corresponding signals S14, S15, and S16 (the received voltage levels) respectively. When any of the voltages V1, V2, and V3 is not at its optimum level set for the electronic device 60, the power supply device 10 controls the voltage V1, V2, or V3 to its optimum level in response to the voltage adjust signal (the received voltage level) received from the electronic device 60.

### Effect of the Embodiments

Both the control circuit 10A for a power supply device and the power supply device 10 of the embodiments allow the interface controller 21 to receive the voltage adjust signals S14 to S16 and the flash memory 22 to store initial data (initial setting levels) beforehand for determining the initial levels of the voltages V1 to V3 and the optimum levels of the voltages for the electronic device 60 corresponding to the voltage adjust signals S14 to S16 so that the voltages V1 to V3 are supplied to the electronic device 60 after modified in response to the data (of initial setting levels) and the optimum levels. Accordingly, when the power supply device 10 is switched on, its voltages V1 to V3 are set up to the initial levels determined by the initial setting levels stored in the flash memory 22 and the optimum levels for the electronic device 60 can be stored in the flash memory 22. When the power supply device 10 is switched on again after the interruption, its voltages V1 to V3 can readily be set up to their optimum levels desired by the electronic device 60 in response to the optimum setting levels (the initial setting levels) stored in the flash memory 22. As the result, the time of the power supply device 10 required for setting up the voltages V1 to V3 to the optimum setting levels for the electronic device 60 in response to the optimum setting levels stored in the flash memory 22 can be minimized more than that for adjusting the voltages V1 to V3 every time when the power supply device 10 is started up to energize the electronic device 60, hence enabling the setting of the voltages V1 to V3 to the optimum levels rapidly and efficiently.

Similarly, the control method of the power supply device 10 according to the embodiment allows, while the voltage adjust signals S14 to S16 have been received, the initial data (initial setting levels) for determining the initial levels of the voltages V1 to V3 to be stored beforehand and the optimum levels of the voltages for the electronic device 60 determined by the voltage adjust signals S14 to S16 to be stored so that the voltages V1 to V3 are supplied to the electronic device 60 after modified in response to the data (of initial setting levels) and the optimum levels. Accordingly, when the power supply device 10 is switched on, its voltages V1 to V3 are set up to the initial levels determined by the initial setting levels and the optimum levels for the electronic device 60 can be stored. In the control method of the power supply device 10, when the power supply device 10 is switched on again after the interruption, its voltages V1 to V3 can readily be set up to their optimum levels desired by the electronic device 60 in response to the optimum setting levels (the initial setting levels) stored beforehand. As the result, the time of the power supply device 10 required for setting up the voltages V1 to V3 to the optimum setting levels for the electronic device 60 in response to the optimum setting levels can be minimized more than that for adjusting the voltages V1 to V3 every time when the power supply device 10 is started up to energize the electronic device 60, hence enabling the setting of the voltages V1 to V3 to the optimum levels rapidly and efficiently.

Also, both the control circuit 10A for a power supply device and the power supply device 10 of the embodiments allow the flash memory 22 and the registers REG1 to REG3 to operate that when the power supply device 10 is switched on, the registers REG1 to REG3 hold the initial data (initial setting levels) read out from the flash memory 22 by the data processor 23 and when the power supply device 10 supplies the electronic device 60 with the voltage such as V1, hold the optimum levels of the voltage for the electronic device 60 determined by the voltage adjust signals S14 to S16. Accordingly, when the power supply device 10 is switched on, the voltage such as V1 of the power supply device 10 is set up to its initial setting level with reference to the initial data (initial setting levels) held in the registers REG1 to REG3. When the power supply device 10 supplies the electronic device 60 with the voltage such as V1, the voltage such as V1 of the power supply device 10 is set up to its optimum level with reference to the optimum levels held in the registers REG1 to REG3.

Similarly, the control method of a power supply device according to the embodiment allows, when the power supply device 10 is switched on, the initial data (initial setting levels) stored in the nonvolatile mode to be read out and stored in the volatile mode and, when the power supply device 10 supplies the electronic device 60 with the voltage such as V1, the optimum levels of the voltage for the electronic device 60 determined by the voltage adjust signals S14 to S16 to be stored in the volatile mode. Accordingly, when the power supply device 10 is switched on, the voltage such as V1 of the power supply device 10 is set up to its initial setting level with reference to the data (of initial setting levels) stored in the volatile mode. When the power supply device 10 supplies the electronic device 60 with the voltage such as V1, the voltage such as V1 of the power supply device 10 is set up to its optimum level with reference to the optimum levels with reference to the optimum levels stored in the volatile mode.

Moreover, both the control circuit 10A for a power supply device and the power supply device 10 of the embodiments allow the first to third DC/DC converters 30 to 50 to supply the electronic device 60 with the voltages V1 to V3 which are modified in response to the initial data (initial setting levels) or the optimum levels stored in the registers REG1 to REG3. Accordingly, adjusting the voltages V1 to V3 to their initial settings separately is not needed at every time when the power supply device 10 is switched on. The electronic device 60 can effectively be supplied with the voltages V1 to V3 by the first to third DC/DC converters 30 to 50 with reference to the initial setting levels. In addition, in the control circuit 10A for a power supply device and the power supply device 10, adjusting the voltages V1 to V3 to their initial settings separately is not needed when the power supply device 10 supplies the electronic device 60 with the voltages V1 to V3. Instead, the voltages V1 to V3 can be set up to their optimum levels efficiently and rapidly by the first to third DC/DC converters 30 to 50 with reference to the optimum levels stored in the registers including REG1.

Similarly, the control method of a power supply device according to the embodiment allows the electronic device 60 to be supplied with the voltages V1 to V3 which are modified in response to initial data (initial setting levels) or the optimum levels stored at the volatile mode. Accordingly, adjusting the voltages V1 to V3 to their initial settings separately is not needed at every time when the power supply device 10 is switched on. The electronic device 60 can effectively be supplied with the voltages V1 to V3 determined by the initial setting levels. In addition, the control method of the power supply device 10 need not adjust the voltages V1 to V3 to their initial settings separately when the power supply device 10 supplies the electronic device 60 with the voltages V1 to V3. Instead, the voltages V1 to V3 can be set up to their optimum levels efficiently and rapidly with reference to the optimum levels stored at the volatile mode for the electronic device 60.

Both the control circuit 10A for a power supply device and the power supply device 10 of the embodiments allow the registers REG1 to REG3 to store the optimum levels for the electronic device 60 in place of the initial data (initial setting levels) when the power supply device 10 supplies the electronic device 60 with the voltages V1 to V3. Accordingly, when the power supply device 10 supplies the electronic device 60 with the voltages V1 to V3, the voltages V1 to V3 can be set up to its optimum levels efficiently and rapidly in response to the optimum levels stored in the registers REG1 to REG3 for the electronic device 60.

Similarly, the control method of the power supply device 10 according to the embodiment allows the optimum levels for the electronic device 60 to be stored in place of the initial data (initial setting levels) in the nonvolatile mode when the power supply device 10 supplies the electronic device 60 with the voltages V1 to V3. Accordingly, the voltages V1 to V3 can be set up to its optimum levels efficiently and rapidly in response to the optimum levels stored in the nonvolatile mode.

Both the control circuit 10A for a power supply device and the power supply device 10 of the embodiments allow the data processor 23 to write and store the data (the received voltage levels) of the voltage adjust signals S14 to S16 in place of the initial data (initial setting levels) in the flash memory 22. Accordingly, the data (the received voltage levels) for determining the optimum levels of the voltages V1 to V3 can be stored in the flash memory 22 (a nonvolatile storage unit) without losing any data.

Similarly, the control method of the power supply device 10 according to the embodiment allows the data (the received voltage levels) of the voltage adjust signals to be stored in place of the initial data (initial setting levels) stored beforehand in the nonvolatile mode. Accordingly, the data (the received voltage levels) for determining the optimum levels of the voltages V1 to V3 can be stored in the nonvolatile mode without losing any data.

The control circuit 10A for a power supply device and the power supply device 10 of the embodiments allow the flash memory 22 (a nonvolatile storage unit) to hold the voltage adjust data (the received voltage levels). Accordingly, the voltage adjust data (received voltage levels) can be securely stored in the nonvolatile mode without losing any data even when the power supply is interrupted.

Similarly, the control method of the power supply device 10 according to the embodiment allows the voltage adjust data (the received voltage levels) of the voltage adjust signals to be stored in the nonvolatile mode. Accordingly, the voltage adjust data (the received voltage levels) can securely be stored without losing any data.

Both the control circuit 10A for a power supply device and the power supply device 10 of the embodiments allow the interface controller 21 to output the voltage adjust signals S14 to S16 to the registers REG1 to REG3 and the data processor 23 so that the voltage adjust signals S14 to S16 (the voltage adjust data) are stored in the registers REG1 to REG3 (volatile storage unit) and their voltage adjust data (the received voltage levels)corresponding to the signals S14 to S16 are stored in the flash memory 22 (a nonvolatile storage unit). While the voltage adjust data are stored in the registers REG 1 to REG3, the data of the received voltage levels are stored in the flash memory 22 in a parallel manner. Accordingly, the power supply device 10 can be improved in the efficiency as compared with the case that the voltage adjust data and the data of the received voltage levels are stored in a succession in the registers REG 1 to REG3 and in the flash memory 22.

Similarly, the control method of the power supply device 10 according to the embodiment allows the voltage adjust data to be stored in the volatile mode and the data of the received voltage levels to be stored in the nonvolatile mode. While the voltage adjust data are stored in the volatile mode, the data of the received voltage levels are stored in the nonvolatile mode in a parallel manner. Accordingly, the power supply device 10 can be improved in the efficiency as compared with the case that the voltage adjust data and the data of the received voltage levels are stored in a succession in the volatile mode and in the nonvolatile mode.

The present invention is not limited to the foregoing embodiments but maybe implemented by being partially modified in the construction without departing from the scope of the present invention. The control circuit 10A for a power supply device and the power supply device 10 of the embodiments allow the voltage adjust signals S14 to S16 (the voltage adjust data) to be stored in the registers REG1 to REG3 (volatile storage unit) and the data of the received voltage levels corresponding to the voltage adjust signals S14 to S16 to be stored in the flash memory 22 (a nonvolatile storage unit). Alternatively, the voltage adjust signals S14 to S16 (the voltage adjust data) may be stored in the registers REG1 to REG3 (volatile storage unit) before the data of the received voltage levels are stored in the flash memory 22 (a nonvolatile storage unit). Accordingly, as the voltages V1 to V3 to be supplied to the electronic device 60 have been set to the optimum levels efficiently and rapidly in response to the voltage adjust data stored in the registers REG1 to REG3, the data of the received voltage levels are stored in the flash memory 22 without losing any data. In other words, the voltages V1 to V3 to be supplied to the electronic device 60 can be set up to the optimum levels at priority before the data of the received voltage levels are stored in the flash memory 22 without losing data.

The control method of the power supply device 10 may be modified in which the voltage adjust signals S14 to S16 (the voltage adjust data) are stored in the volatile mode before the data of the received voltage levels are stored in the nonvolatile mode. Accordingly, as the voltages V1 to V3 to be supplied to the electronic device 60 have been set up to the optimum levels efficiently and rapidly in response to the voltage adjust data stored in the volatile mode, the data of the received voltage levels are stored without losing any data. In other words, the voltages V1 to V3 to be supplied to the electronic device 60 can be set up to the optimum levels at priority before the data of the received voltage levels are stored.

Although the power supply device 10 of the embodiment has the output unit for three channels (CH1 to CH3) as shown in FIG. 1, it may be provided with four or more output unit of corresponding channels. Also, the flash memory 22 may hold a control program for the power supply device 10 in addition to the initial data (initial setting levels). The control circuit 10A in the power supply device 10 of the embodiment may consist of one or more semiconductor chips. The power supply device 10 may also consist of one or more semiconductor chips. The power supply device 10 and the control circuit 10A thereof may be provided in a module. Furthermore, the electronic device may include a power supply device equipped with a control circuit and DC/DC converters.

The control circuit for a power supply device, the power supply device, and the control method thereof according to the present invention is arranged to receive and store the demand levels of the voltage from an electronic device to be energized while the initial setting levels for determining initial voltage levels have been stored beforehand. This allows the voltages to be supplied to be controlled in response to the initial setting levels and the demand levels. As the result, the time required for setting up the voltages to the optimum setting levels demanded by the electronic device in response to the setting levels stored can be minimized more than that for adjusting the voltages every time when the power supply device is started up to energize the electronic device, hence enabling the setting of the voltages to the optimum levels rapidly and efficiently.

What is claimed is:

1. A control circuit for a power supply device for supplying a required voltage to a device which supplies an initial voltage and then demands to receive the required voltage different from the initial voltage, the control circuit comprising:
a communication unit for receiving a demand level for the required voltage; and
a storage unit for storing an initial setting level used to determine the initial voltage beforehand and storing the demand level received by the communication unit, wherein
the initial voltage or the required voltage is controlled in response to the initial setting level or the demand level.

2. The control circuit for a power supply device according to claim 1, comprising:
a nonvolatile storage unit in which at least the initial setting level is stored beforehand, a register unit for storing the initial setting level and the demand level, wherein the register unit stores the initial setting level read out from the nonvolatile storage unit when the power supply device is started and stores the demand level received by the communication unit when the power supply device is operated.

3. The control circuit for a power supply device according to claim 2, further comprising:
a voltage controller unit for controlling the initial voltage or the required voltage in response to the initial setting level or the demand level stored in the register unit.

4. The control circuit for a power supply device according to claim 2, wherein
the register unit stores the demand level in place of the initial setting level when the power supply device is operated.

5. The control circuit for a power supply device according to claim 2, wherein
the nonvolatile storage unit stores the demand level.

6. The control circuit for a power supply device according to claim 5, wherein
the nonvolatile storage unit stores the demand level in place of the initial setting level stored beforehand.

7. The control circuit for a power supply device according to claim 5, wherein
the demand level is received by the communication unit and then stored in the register unit and simultaneously stored in the nonvolatile storage unit.

8. The control circuit for a power supply device according to claim 5, wherein
the demand level, after received by the communication unit, is stored in the register unit and then stored in the nonvolatile storage unit.

9. A power supply device for supplying a required voltage to a device which supplies an initial voltage and then demands to receive the required voltage different from the initial voltage, the power supply device comprising:
a communication unit for receiving a demand level for the required voltage;
a storage unit for storing an initial setting level used to determine the initial voltage beforehand and storing the demand level received by the communication unit, wherein
the initial voltage or the required voltage is controlled in response to the initial setting level or the demand level.

10. The power supply device according to claim 9, comprising:
a nonvolatile storage unit in which at least the initial setting level is stored beforehand, a register unit for storing the initial setting level and the demand level, wherein the register unit stores the initial setting level read out from the nonvolatile storage unit when the power supply device is started and stores the demand level received by the communication unit when the power supply device is operated.

11. The power supply device according to claim 10, comprising:
a voltage controller unit for controlling the initial voltage or the required voltage in response to the initial setting level or the demand level stored in the register unit.

12. The power supply device according to claim 10, wherein
the register unit stores the demand level in place of the initial setting level when the power supply device is operated.

13. The power supply device according to claim 10, wherein
the nonvolatile storage unit stores the demand level.

14. The power supply device according to claim 13, wherein
the nonvolatile storage unit stores the demand level in place of the initial setting level stored beforehand.

15. The power supply device according to claim 13, wherein
the demand level is received by the communication unit and then is stored in the register unit and is simultaneously stored in the nonvolatile storage unit.

16. The power supply device according to claim 13, wherein
the demand level, after received by the communication unit, is stored in the register unit and then is stored in the nonvolatile storage unit.

17. A control method of a power supply device for supplying a required voltage to a device which supplies an initial voltage and then demands to receive the required voltage different from the initial voltage, the method comprising steps of:
receiving a demand level for the required voltage;
storing an initial setting level used to determine the initial voltage beforehand and storing the demand level received; and
controlling the initial voltage or the required voltage in response to the initial setting level or the demand level.

18. The control method of a power supply device according to claim 17, further comprising steps of:
storing at least the initial setting level beforehand in a nonvolatile mode; storing the initial setting level and the demand level in a volatile mode; reading out the initial setting level stored in the nonvolatile mode and storing the initial setting level in a volatile mode when the power supply device is started, and storing the demand level received in the volatile mode when the power supply device is operated.

19. The control method of a power supply device according to claim 18, wherein
the demand level is stored in the nonvolatile mode.

20. The control method of a power supply device according to claim 19, wherein
the demand level is stored in the nonvolatile mode in place of the initial setting level stored beforehand in the nonvolatile mode.
